(19) United States
(12) Patent Application Publication
(10) Pub. No.: US 2026/0362918 A1
(43) Pub. Date: Nov. 12, 2026

(54) ORGANIC LIGHT EMITTING DISPLAY DEVICE

(71) Applicant: LG Display Co., Ltd., Seoul (KR)

(72) Inventors: Sung Jin PARK, Paju-si (KR); Gyu Ho LEE, Paju-si (KR); Sin Chul KANG, Paju-si (KR)

(73) Assignee: LG Display Co., Ltd., Seoul (KR)

(21) Appl. No.: 19/376,635

(22) Filed: Oct. 31, 2025

(30) Foreign Application Priority Data
Dec. 31, 2024 (KR) 10-2024-0202398

(51) Int. Cl. H10K 59/131; H10K 102/00

(52) U.S. Cl. CPC H10K 59/131; H10K 2102/311

(57) ABSTRACT

An example of an organic light emitting display device includes a first substrate having a plurality of sub-pixels, a second substrate disposed on one side of the first substrate and having a pad region, a bending region connecting the first substrate and the second substrate, an etching prevention layer disposed in the bending region, a circuit layer disposed on the first substrate, and a light emitting element connected to the circuit layer. The bending region includes a first bending region where a plurality of connection wires are located, and second bending regions provided on both sides of the first bending region. A plurality of reinforcement patterns are provided in the second bending regions.

### CROSS-REFERENCE TO RELATED APPLICATION

This application claims priority to and the benefit of Korean Patent Application No. 10-2024-0202398, filed in the Republic of Korea on Dec. 31, 2024, the disclosure of which is hereby expressly incorporated by reference in its entirety.

### BACKGROUND

### Field

The present specification relates to an organic light emitting display device.

### Discussion of Related Art

Electroluminescent display devices can be classified into inorganic light emitting display devices and organic light emitting display devices according to the material of the light emitting layer.

Active matrix type organic light emitting display devices include self-emitting organic light emitting diodes (hereinafter referred to as "OLEDs"), and have advantages of fast response speed, high luminous efficiency, brightness, and viewing angle. In the organic light emitting display devices, an OLED is formed in each of the pixels. The organic light emitting display devices not only have fast response speed and are excellent in luminous efficiency, brightness, and viewing angle, but also have excellent contrast ratio and color reproducibility because they can express black grayscale as complete black.

### SUMMARY OF THE DISCLOSURE

An object of one or more embodiments of the present disclosure is to provide an organic light emitting display device capable of reducing or preventing stress of connection wires at edges of a bending region of a substrate.

Another object of one or more embodiments of the present disclosure is to provide an improved display device, which address the limitations and disadvantages associate with the related art display devices.

The objects according to the embodiments of the present disclosure are not limited to the above-mentioned objects, and other objects not mentioned will be clearly understood by those skilled in the art from the following description.

An organic light emitting display device according to an embodiment of the present disclosure comprises a first substrate including a plurality of sub-pixels; a second substrate disposed on one side of the first substrate and including a pad region; a bending region connecting the first substrate and the second substrate; an etching prevention layer disposed in the bending region; a circuit layer disposed on the first substrate; and a light emitting element connected to the circuit layer, wherein the bending region includes a first bending region where a plurality of connection wires are located, and second bending regions provided on both sides of the first bending region, wherein a plurality of reinforcement patterns can be provided in the second bending regions.

An organic light emitting display device according to another embodiment of the present disclosure comprises a first substrate including a plurality of sub-pixels; a second substrate disposed on one side of the first substrate and including a pad region; and a bending region connecting the first substrate and the second substrate, wherein the bending region includes a first bending region where a plurality of connection wires are located, and second bending regions provided on both sides of the first bending region, wherein a plurality of reinforcement patterns can be provided in the second bending regions.

Specific details according to various examples of the present disclosure other than the solutions to the above-mentioned problems are included in the following description and drawings.

According to aspects of the present disclosure, since the reinforcement patterns are provided at edge portions on both sides of the bending region, they can replace the role of the conventional micro coating layer, and thus the micro coating layer does not need to be separately formed, thereby simplifying the manufacturing process.

According to aspects of the present disclosure, by disposing the reinforcement patterns at edge portions on both sides of the bending region of the substrate during the bezel bending process of the organic light emitting display device, stress on the connection wires at edges of the bending region can be reduced or eliminated.

According to aspects of the present disclosure, by disposing reinforcement patterns at edge portions on both sides of the bending region, reliability can be improved by alleviating stress which can be caused by expansion/contraction occurring in high and low temperature environments at edge regions of the substrate.

The effects of the present disclosure are not limited to the effects mentioned above, and other effects not mentioned will be clearly understood by those skilled in the art from the following description.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, in which:

FIG. 1 is a block diagram of an organic light emitting display device according to a first embodiment of the present disclosure;

FIG. 2 is a plan view showing an organic light emitting display device according to the first embodiment of the present disclosure.

FIG. 3 is an enlarged plan view of an organic light emitting display device according to the first embodiment of the present disclosure;

FIG. 4 is a cross-sectional view taken along line I-I' of FIG. 3 according to the first embodiment of the present disclosure;

FIG. 5 is a cross-sectional view taken along line II-II' of FIG. 3 according to the first embodiment of the present disclosure;

FIG. 6 is a cross-sectional view taken along line III-III' of FIG. 3 according to the first embodiment of the present disclosure;

FIG. 7 is a plan view showing an organic light emitting display device according to a second embodiment of the present disclosure;

FIG. 8 is a plan view showing an organic light emitting display device according to a third embodiment of the present disclosure;

FIG. 9 is a cross-sectional view taken along line IV-IV' of FIG. 8 according to the third embodiment of the present disclosure;

FIG. 10 is a plan view showing an organic light emitting display device according to a fourth embodiment of the present disclosure;

FIG. 11 is a cross-sectional view taken along line V’-V of FIG. 10 according to the fourth embodiment of the present disclosure; and

FIG. 12 is a schematic side cross-sectional view showing a bending state of the organic light emitting display device according to the first or other embodiment of the present disclosure.

### DETAILED DESCRIPTION OF THE EMBODIMENTS

The advantages and features of the present disclosure, and methods of achieving them will be apparent from the embodiments described in detail below in conjunction with the accompanying drawings. However, the present disclosure is not limited to the following embodiments disclosed herein, but can be implemented in various different forms; rather, the present embodiments are provided to make the disclosure of the present specification complete and to enable those skilled in the art to fully comprehend the scope of the present disclosure.

The shapes, sizes, proportions, angles, numbers, and the like of elements shown in the drawings to illustrate embodiments of the present disclosure are merely illustrative and are not intended to be limiting. Identical reference numerals can designate identical components throughout the description. Further, in describing the present disclosure, detailed descriptions of related known technologies can be omitted so as not to obscure the essence of the present disclosure. The terms such as "including," "having," and "consisting of" as used herein are generally intended to allow other components to be added unless the terms are used with the term "only." References to components of a singular noun include the plural of that noun, unless specifically stated otherwise.

In the interpretation of components, they are construed to include margins of error, even if not explicitly stated.

When describing a positional relationship, for example, "on top of," "above," "below," "next to," or "adjacent to" describes the positional relationship of two parts, one or more other parts can be located between the two parts, unless "immediately," "directly," or "near to" is used.

When describing a temporal relationship, "after," "subsequently to," "following," or, "before" describes a temporal antecedent or consequent relationship, which may not be continuous unless "immediately," or "directly" is used.

The first, the second, and so on are used to describe various components, but these components are not limited by these terms. These terms are used only to distinguish one component from another. Therefore, a first component referred to below can be a second component within the technical spirit of the present disclosure.

Terms such as first, second, A, B, (a), or (b) can be used to describe elements of the embodiments of the present disclosure. Such terms are intended only to distinguish one component from another and are not intended to define the nature, sequence, order, or number of such components.

When a component is described as being "connected," "coupled", "accessed," or "attached" to another component, it is to be understood that the component can be directly connected, coupled, accessed, or attached to the other component, but that there can also be other components interposed between the respective components which can be indirectly connected, coupled, accessed, or attached, unless specifically stated otherwise.

When a component is described as being "in contact" or "overlapping" with another component, it is to be understood that the component can be in direct contact or overlap with the other component, but other components can also be "interposed" between the these components, resulting in indirect contact or overlap, unless specifically stated otherwise.

The term "at least one" should be understood to include all combinations of one or more of the associated components. For example, the meaning of "at least one of the first, second, and third components" can be understood to include not only the first, second, or third component, but also any combination of two or more of the first, second, and third components.

The terms such as "the first direction," "the second direction," "the third direction," "the X-axis direction," "the Y-axis direction," and "the Z-axis direction" are not to be interpreted solely as a geometric relationship in which the relationship to one another is perpendicular, but can refer to a broader range of orientations in which the configurations of the present disclosure can function. Further, the term “can” fully encompasses all the meanings of the term “may” and vice versa.

As used herein, a "device" can include a display device, such as a liquid crystal module (LCM) or an organic light-emitting display (OLED) module, which includes a display panel and a driver for driving the display panel. It can also include a set electronic apparatus or a set device, such as a laptop computer, a television set, a computer monitor, a vehicle or an automotive apparatus, or an equipment apparatus including another form of vehicle, and a mobile electronic apparatus, such as a smart phone or an electronic pad and the like, which is a complete product or finished product including LCMs, OLED modules, and the like.

Therefore, the device in the present disclosure can include a display device itself, such as an LCM module, OLED module, and the like, and a set device which is an application product or an end-consumer device including the LCM, OLED module, and the like.

Furthermore, in some embodiments, an LCM module and an OLED module composed of a display panel and a driver can be expressed as a "display device", and an electronic device as a finished product including the LCM, OLED module (or panel) can be distinguished and expressed as a "set device".

For example, the display device can include a liquid crystal display (LCD) panel or an organic light-emitting diode (OLED) display panel, and a source printed circuit board (PCB) which is a control part for driving the display panel. The set device can further include a set PCB, which is a set control part electrically connected to the source PCB to drive the entire set device.

The display panels used in the embodiments of the present disclosure can be any type of display panels such as a liquid crystal display panel, an organic light-emitting diode (OLED) display panel, and an electroluminescent display panel, but the embodiments are not limited thereto. For example, the display panel can be a display panel capable of generating sound by being vibrated by a vibration device according to the embodiments of the present disclosure. The display panel applied to the display device according to the embodiments of the present disclosure is not limited to the form or size of the display panel.

Each of the features of various embodiments of the present disclosure can be coupled or combined with one another in whole or in part, and can be technologically interlocked and operated in various ways, and each of the embodiments can be carried out independently or in conjunction with one another.

Hereinafter, various embodiments of the present disclosure will be described in detail with reference to the accompanying drawings. All the components of each display device according to all embodiments of the present disclosure are operatively coupled and configured. The scale of the components shown in the drawings has a different scale from the actual scale for convenience of explanation and is not limited to the scale shown in the drawings.

The display device of the present disclosure can be applied to various display devices such as organic electroluminescent display devices, electrophoretic display devices, mini light emitting diode (LED) display devices, and micro LED display devices, but hereinafter, an organic electroluminescent display device will be described as an example for convenience of explanation.

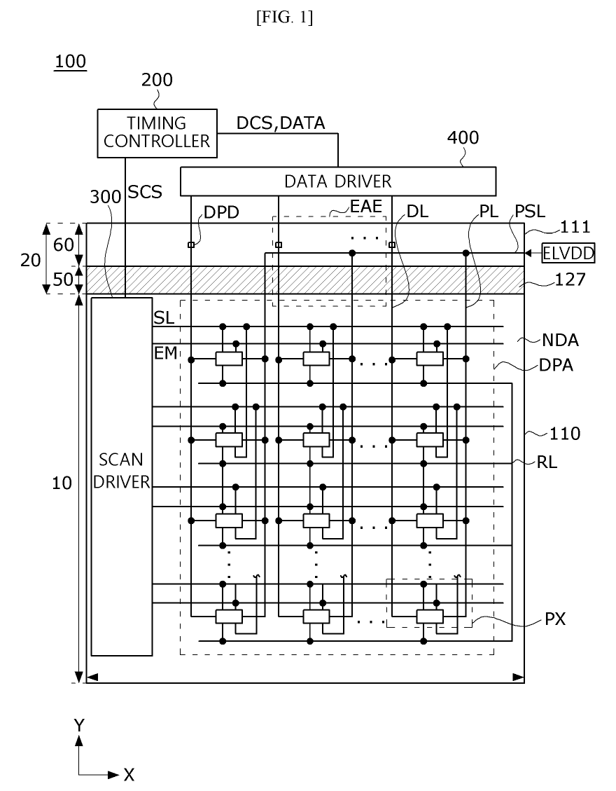

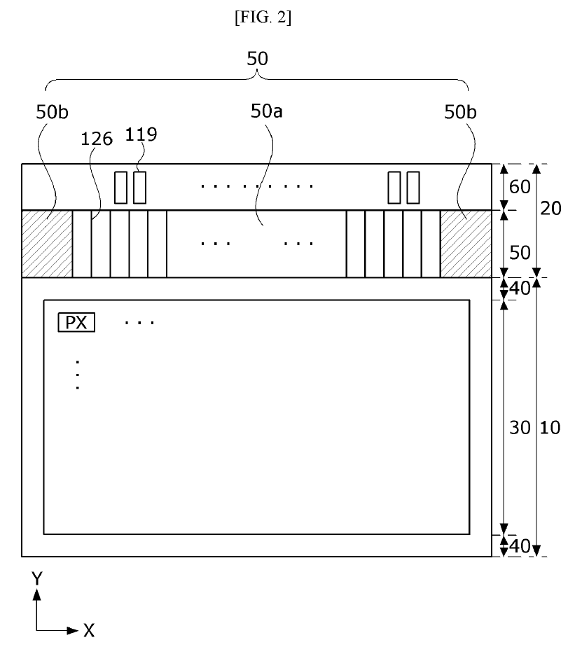

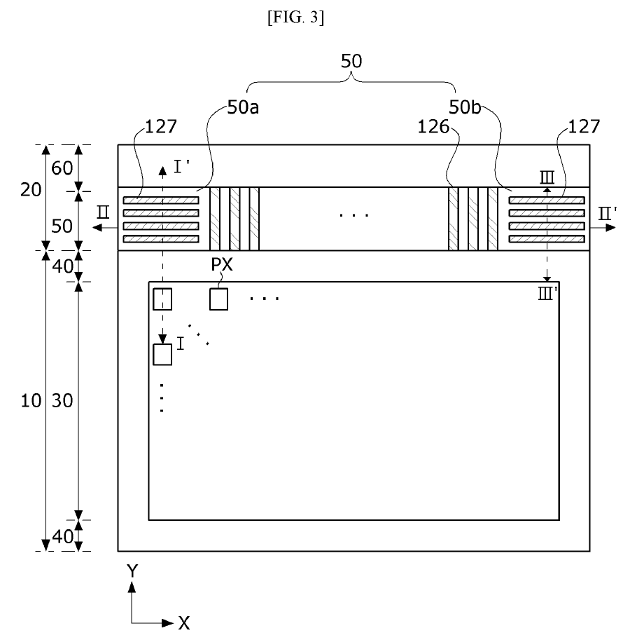

FIG. 1 is a block diagram of an organic light emitting display device according to one or more embodiments of the present disclosure. FIG. 2 is a plan view showing an organic light emitting display device according to an embodiment of the present disclosure. FIG. 3 is an enlarged plan view of an organic light emitting display device according to an embodiment of the present disclosure.

Referring to FIG. 1, an organic light emitting display device 100 can include a timing controller 200, a scan driver 300, a data driver 400, and a display part DPA.

The timing controller 200 can receive input image signals and generate image data. The timing controller 200 can output the image data and various control signals DCS and SCS.

The scan driver 300 can receive a scan control signal SCS from the timing controller 200.

The scan control signal SCS can include a vertical start signal that initiates operation of the scan driver, a clock signal that determines output timing of signals, and the like. The scan driver 300 can generate a plurality of scan signals and sequentially output the plurality of scan signals to a plurality of gate lines SL to be described later. The scan driver can generate a plurality of emission control signals in response to the scan control signal SCS and output the plurality of emission control signals to a plurality of emission control lines EM to be described later.

The data driver 400 receives a data control signal DCS and image data DATA from the timing controller 200. The data driver 400 converts the image data DATA into data signals and outputs the data signals to a plurality of data lines DL to be described later. The data signals can be analog voltages corresponding to grayscale values of the image data.

The display part DPA can include a plurality of gate lines SL, a plurality of emission control lines EM, a plurality of data lines DL, and a plurality of pixels PX disposed on a substrate 110. The plurality of gate lines SL can extend in a first direction X and be arranged in a second direction Y crossing the first direction. Each of the plurality of emission control lines EM can be arranged parallel to a corresponding gate line among the plurality of gate lines SL. The plurality of data lines DL can be insulated from and cross the plurality of gate lines SL.

A pixel PX can be connected to a gate line SL, an emission control line EM, and a data line DL. The pixel PX can receive a first voltage ELVDD and a second voltage ELVSS at a level lower than the first voltage ELVDD. The pixel PX can include a common power line PL applying the first voltage ELVDD and an initialization line RL receiving an initialization voltage Vint. The first voltage ELVDD can also be referred to as a common voltage.

The pixel PX can include an organic light emitting element OLED and a circuit part that controls light emission of the organic light emitting element OLED. The circuit part can include a plurality of thin film transistors and a capacitor. The display part DPA can include red pixels emitting red light, green pixels emitting green light, and blue pixels emitting blue light. The organic light emitting element OLED of the red pixel, the organic light emitting element OLED of the green pixel, and the organic light emitting element OLED of the blue pixel can include organic light emitting layers OL made of different materials.

Referring to FIG. 2, the organic light emitting display device 100 can include a display region 10 and a non-display region 20, and the non-display region 20 can include a bending region 50 and a pad region 60. A plurality of pixels PX can be disposed in the display region 10, and the pad region 60 can be located spaced apart from the display region 10.

The display region 10 can include a pixel region 30 from which light is emitted and a peripheral region 40 surrounding the pixel region 30. In an example embodiment, pixels PX (e.g., pixel structures) that emit light can be disposed in the pixel region 30, and a plurality of wires can be disposed in the peripheral region 40. The wires can electrically connect pad electrodes 119 and the pixels PX. For example, the wires can include data signal wires, scan signal wires, emission signal wires, power voltage wires, and the like. Additionally, the scan driver, the data driver, and the like can be disposed in the peripheral region 40. Moreover, a part of the peripheral region 40 can be interposed between the pixel region 30 and the bending region 50.

Although FIG. 2 shows that the width of the peripheral region 40 surrounding the pixel region 30 is the same, the configuration of the present disclosure is not limited thereto. For example, the peripheral region 40 can include a first region extending along the first direction X corresponding to a column direction in a plan view of the organic light emitting display device 100 and a second region extending along the second direction Y corresponding to a row direction. In other words, the first region of the peripheral region 40 can be located on both sides of the pixel region 30, and the second region of the peripheral region 40 can be located at the upper portion of the pixel region 30 and the portion adjacent to the bending region 50.

Here, the width extending in the second direction Y of the first region can be relatively smaller than the width extending in the first direction X of the second region. Optionally, the width in the second direction Y of the bending region 50 and the pad region 60 can be smaller than the width in the second direction Y of the display region 10.

Referring to FIGS. 2 and 3, as the bending area 50 is bent around the second direction Y as an axis, the pad area 60 can be positioned on a bottom surface of the organic light emitting display device 100.

The pad electrodes 119 electrically connected to external devices can be disposed in the pad region 60. The bending region 50 can be located between the display region 10 and the pad region 60.

The bending region 50 can include a first bending region 50a and second bending regions 50b disposed on both sides of the first bending region 50a.

The first bending region 50a can include a connection wires 126. The connection wires 126 can electrically connect signal lines, such as the data line DL and the common power line PL, disposed in the display area 10, to the pad electrodes 119 disposed in the pad region 60.

In the second bending regions 50b, reinforcement patterns 127 can be disposed perpendicular to the connection wires 126 and spaced apart from each other at regular intervals. The reinforcement patterns 127 may not connected to the connection wires 126 but are independently disposed and can be disposed perpendicular to the connection wires 126.

In other words, when the pad region 60 is located on the bottom surface of the organic light emitting display device 100, the bending region 50 can have a bent shape. In example embodiments, the organic light emitting display device 100 can further include the connection wires 126. The connection wires 126 can be disposed overlapping the bending region 50 and can electrically connect the signal lines and the pad electrodes 119.

Therefore, the pixels PX disposed in the pixel region 30 and external devices electrically connected to the pad electrodes 119 can be electrically connected through the connection wires 126 disposed in the bending region 50 and the plurality of wires disposed in the peripheral region 40. For example, the external devices can be electrically connected to the organic light emitting display device 100 through a flexible printed circuit board. The external devices can provide data signals, scan signals, emission signals, power voltages, etc. to the organic light emitting display device 100.

A driving integrated circuit can be mounted on the flexible printed circuit board. In other example embodiments, the driving integrated circuit can be mounted on the organic light emitting display device 100 adjacent to the pad electrodes 119.

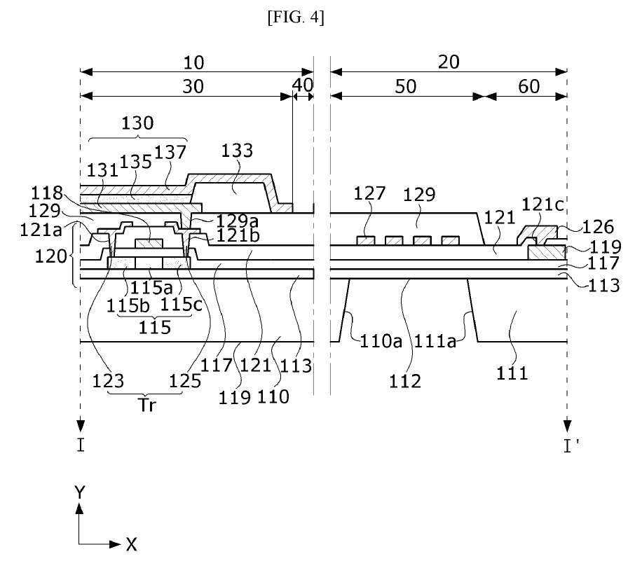

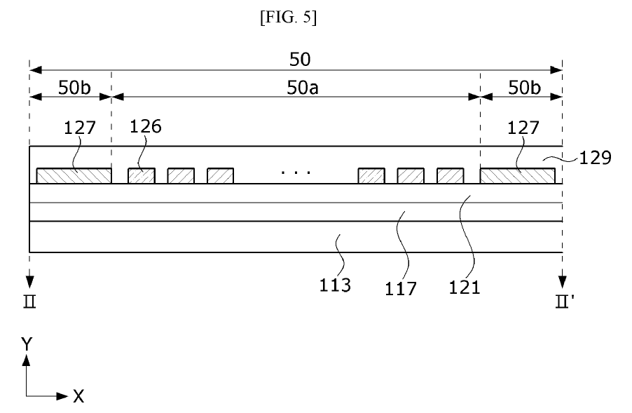

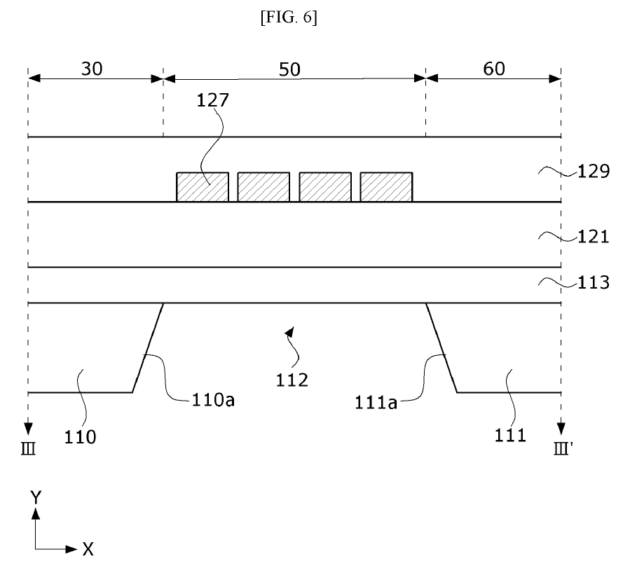

FIG. 4 is a cross-sectional view taken along line I-I' of FIG. 3. FIG. 5 is a cross-sectional view taken along line II-II' of FIG. 3. FIG. 6 is a cross-sectional view taken along line III-III' of FIG. 3.

Referring to FIG. 4, the present disclosure will be described using organic light emitting diodes (OLEDs) as an example among various types of display devices. The present disclosure is not limited thereto.

The display region 10 can include a light emitting element 130 provided in each of a plurality of sub-pixels PX on a first substrate 110 and at least one thin film transistor Tr driving the light emitting element 130.

A buffer layer 113 can be disposed on the first substrate 110 and a second substrate 111. The first substrate 110 includes the display region 10, and the second substrate 111 can include the pad region 60. The bending region 50 can be included between the first substrate 110 and the second substrate 111. In this situation, by folding the second substrate 111 under the first substrate 110 based on the bending region 50, the bezel width of the organic light emitting display device can be reduced.

The buffer layer 113 can be formed as a single layer made of an inorganic insulating film or an organic insulating film, or can be formed as multiple layers in which these films are stacked. In the case of an inorganic insulating film, it can be formed as a single layer or multilayer structure of silicon oxide (SiOx) or silicon nitride (SiNx). The present disclosure is not limited to these. For example, the present disclosure can describe a case where the buffer layer 113 is formed as an organic insulating film as an example.

The buffer layer 113 provided in the bending region 50 of the first substrate 110 can serve as an etching prevention layer. The buffer layer 113 can be provided to prevent etching of components on the substrate during the substrate etching process. The buffer layer 113 can include a material having chemical resistance to glass etching fluid (GEF). For example, the buffer layer 113 can be formed of a type of organic insulating film. Thus, even if the etchant etches the first substrate 110 in the bending region 50 to expose the buffer layer 113, the organic insulating film buffer layer 113 can prevent direct penetration of the etchant into the panel.

In the case of an organic insulating film, it can be any one of photo acryl, polyimide, benzocyclobutene resin, and acrylate, and can be formed as multiple layers in some cases.

Among the buffer layer 113, the buffer layer portion located in the bending region 50 can be used as an etching prevention layer when forming an opening 112 by etching a portion of the lower surface of the first substrate 110 located in the bending region 50. Through the etching process, the first substrate 110 can have a first inclined surface 110a formed under the bending region 50, and the second substrate 111 can have a second inclined surface 111a formed under the bending region 50.

Circuit elements including various signal wires such as data signals and gate signals, thin film transistors such as switching thin film transistors and driving thin film transistors, and capacitors can be formed for each sub-pixel on the buffer layer 113. In the present disclosure, only one arbitrary thin film transistor Tr driving one light emitting element 130 is shown for convenience of explanation, but the organic light emitting display device 100 of the present disclosure can include at least one thin film transistor Tr.

The at least one thin film transistor Tr can include a gate electrode 118 overlapping a channel region 115a of an active layer 115 with a gate insulating film 117 interposed therebetween, and a source electrode 123 and a drain electrode 125 connected to a source region 115b and a drain region 115c on both sides of the channel region 115a, respectively.

The active layer 115 constituting the thin film transistor Tr can be disposed on the buffer layer 113. The active layer 115 of the thin film transistor Tr can include the channel region 115a, and the source region 115b and the drain region 115c on both sides of the channel region 115a. Here, each of the source region 115b and the drain region 115c can be formed of a semiconductor material doped with n-type or p-type impurities. The channel region 115a overlapping the gate electrode 118 can be formed of a semiconductor material not doped with n-type or p-type impurities.

The gate insulating film 117 covering the active layer can be disposed on the buffer layer 113. The gate insulating film 117 can be made of an inorganic insulating material, for example, silicon oxide film (SiOx), silicon nitride film (SiNx), silicon oxynitride film (SiOxNy), or a multilayer thereof. The present disclosure is not limited to these.

The gate electrode 118 overlapping the channel region 115a of the active layer 115 can be disposed on the gate insulating film 117 covering the active layer 115. The pad electrodes 119 disposed in the pad region 60 can be disposed on the gate insulating film 117 in the same layer as the gate electrode 118. The gate electrode 118 of the thin film transistor Tr can overlap the channel region 115a of the active layer 115 with the same width, with the gate insulating film 117 interposed therebetween. For example, the gate electrode 118 and the pad electrodes 119 can be a single layer or multiple layers made of any one of molybdenum (Mo), aluminum (Al), chromium (Cr), gold (Au), titanium (Ti), nickel (Ni), neodymium (Nd), and copper (Cu), or alloys thereof. The present disclosure is not limited to these.

An interlayer insulating film 121 can be disposed on the gate insulating film 117, covering the gate electrode 118 and having a source contact hole 121a and a drain contact hole 121b exposing the source region 115b and the drain region 115c of the active layer 115, respectively, and a pad contact hole 121c exposing the pad electrodes 119 in the pad region 60. The interlayer insulating film 121 can be made of an inorganic insulating material. In this case, the interlayer insulating film 121 can be formed as a single layer or multiple layers of silicon oxide film (SiOx), silicon nitride film (SiNx), or silicon oxynitride film (SiOxNy). The present disclosure is not limited to these.

Referring to FIGS. 5 and 6, a source electrode 123 and a drain electrode 125, the connection wires 126, and the reinforcement patterns 127 can be provided on the same layer on the interlayer insulating film 121. The source electrode 123 and the drain electrode 125 can be located in the display region 10, the connection wires 126 can be located in the first bending region 50a of the bending region 50, and the reinforcement patterns 127 can be located in the second bending regions 50b provided at edge portions on both sides of the first bending region 50a.

In this case, the reinforcement patterns 127 can be disposed independently without being connected to the connection wires 126 at all.

The source electrode 123 and the drain electrode 125 are connected to the source region 115b and the drain region 115c of the active layer 115 through the source contact hole 121a and the drain contact hole 121b, respectively, formed in the interlayer insulating film 121, respectively. The connection wires 126 can be connected to the pad electrodes 119 through the pad contact hole 121c.

For example, the source electrode 123 and the drain electrode 125, the connection wires 126, and the reinforcement patterns 127 can be formed as a single layer of metal materials such as molybdenum (Mo), aluminum (Al), chromium (Cr), gold (Au), titanium (Ti), nickel (Ni), neodymium (Nd), or copper (Cu), or alloys thereof, or can be formed in a multilayer structure using these. However, the present disclosure is not limited to these.

The source electrode 123 and the drain electrode 125 are disposed in the display region 10, the connection wires 126 are disposed in the first bending region 50a, and the reinforcement patterns 127 can be disposed in the second bending regions 50b provided at edge portions on both sides of the first bending region 50a. However, the present disclosure is not limited thereto.

The connection wires 126 disposed in the bending region 50 can be electrically connected to the pad electrodes 119 through the pad contact hole 121c formed in the interlayer insulating film 131 of the pad region 60. Additionally, the reinforcement patterns 127 can be disposed independently and spaced apart from each other without being electrically connected to the connection wires 126.

Therefore, referring to FIG. 4, the thin film transistor Tr can include the active layer 115, the gate electrode 118 overlapping the active layer 115 with the gate insulating film 117 interposed therebetween, and the source electrode 123 and the drain electrode 125 connected to the source region 115b and the drain region 115c of the active layer 115 on both sides of the gate electrode 118, respectively.

A planarization layer 129 covering the source electrode 123 and the drain electrode 125 constituting the thin film transistor can be disposed on the interlayer insulating film 121. For example, the planarization layer 129 can be formed of an inorganic insulating film or an organic insulating film. In the case of an inorganic insulating film, it can be formed as a single layer or multiple layers of silicon oxide film (SiOx), silicon nitride film (SiNx), or silicon oxynitride film (SiOxNy). The present disclosure is not limited to these. In the case of an organic insulating film, it can be any one of photo acryl, polyimide, benzocyclobutene resin, and acrylate, and can be formed as multiple layers in some cases.

The planarization layer 129 can include a drain contact hole 129a exposing the drain electrode 125.

A first electrode 131 connected to the thin film transistor Tr through the drain contact hole 129a can be disposed on the planarization layer 129. For example, the first electrode 131 can be formed as a single layer of metal materials such as molybdenum (Mo), aluminum (Al), chromium (Cr), gold (Au), titanium (Ti), nickel (Ni), neodymium (Nd), or copper (Cu), or alloys thereof, or can be formed in a multilayer structure using these.

On the other hand, referring to FIG. 4, the first electrode 131 can be formed in a multilayer structure including a transparent conductive film and an opaque conductive film with high reflective efficiency. The transparent conductive film of the first electrode 131 can be made of a material with a relatively large work function value such as Indium tin oxide (ITO) or indium zinc oxide (IZO), and the opaque conductive film can be formed as a single layer or multiple layers of any one selected from the group consisting of silver (Ag), aluminum (Al), copper (Cu), molybdenum (Mo), titanium (Ti), nickel (Ni), chromium (Cr), or tungsten (W), or alloys thereof. For example, the first electrode 131 can be formed in a structure in which a transparent conductive film, an opaque conductive film, and a transparent conductive film are sequentially stacked, or in a structure in which a transparent conductive film and an opaque conductive film are sequentially stacked.

The first electrode 131 is provided in each of the plurality of sub-pixels PX and can be electrically connected to each thin film transistor Tr.

A bank 133 covering edge portions on both sides of the first electrode 131 can be disposed on the planarization layer 129. For example, the bank 133 can be made of organic materials such as polyimide, acrylate, or benzocyclobutene series resin.

An intermediate layer 135 can be disposed on the first electrode 131. For example, the intermediate layer 135 can be provided over the entire display region 30 of the first substrate 110. Specifically, the intermediate layer 135 can be provided on the first electrode 131 opened by the bank 133, and on the side surfaces and top surface of the bank 133.

The intermediate layer 135 can refer to a single stack organic layer composed of multiple layers including a hole injection layer (HIL), a hole transport layer (HTL), an emission layer (EML), an electron transport layer (ETL), and an electron injection layer (EIL). In some cases, the intermediate layer 135 can have a tandem structure including multiple stacks (first stack and second stack) each having an emission layer and a charge generation layer (CGL) between the stacks. Further, the tandem structure of the intermediate layer 135 is not limited to a 2-stack structure and can consist of multiple stacks of 3 or more stacks.

A second electrode 137 on the intermediate layer 135 can be disposed opposite to the first electrode 131 across the entire display area 10. In some cases, the second electrode 137 can also be disposed in the non-display region 20 to contact the circuit part of the non-display region 20.

When the display device of the present disclosure is a top emission type, the second electrode 137 can be made of a transparent conductive layer. For example, the second electrode 137 can be made of a transparent conductive material such as indium tin oxide (ITO) or indium zinc oxide (IZO).

Therefore, a plurality of light emitting elements 130 including a stacked structure of the first electrode 131, the intermediate layer 135, and the second electrode 137 can be provided on the planarization layer 129. The light emitting element 130 can be driven when current supplied from a power voltage line flows to the second electrode 137 and high voltage current is supplied from the thin film transistor Tr to the first electrode 131, thereby forming an electric field between the first electrode 131 and the second electrode 137 and causing the intermediate layer 135 to emit light.. In this case, the light emitting part, which is the region where light is emitted from the light emitting element 130, can be the region exposed from the bank 133, but the organic light emitting display device 100 of the present disclosure is not limited thereto, and the light emitting part can include even the side surfaces and top surface of the bank 133 where the intermediate layer 135 can be provided.

When the organic light emitting display device 100 of the present disclosure is a top emission type, the first electrode 131 can be formed with higher reflective efficiency than the second electrode 137 to reflect light generated from the intermediate layer 135.

The organic light emitting display device 100 according to an embodiment of the present disclosure can further include an encapsulation layer disposed on the second electrode 137 of the light emitting element 130. The encapsulation layer can be formed of multiple layers. For example, the encapsulation layer can have a structure in which inorganic films and organic films are alternately stacked. The inorganic film can be composed of metal oxides, metal nitrides, metal carbides, and compounds thereof. For example, the inorganic film can include inorganic materials such as AlOx, TiO2, ZrO, SiOx, AlON, AlN, SiNx, SiOxNy, InOx, and YbOx. The organic film can include polymer-based materials. The polymer-based materials can include acrylic resins, epoxy resins, silicone resins, allyl resins, polyimide, and polyethylene.

Referring to FIG. 4, the non-display region 20 can include the bending region 50 and the pad region 60. The bending region 50 is an arbitrary region where the organic display device 100 is bent and can include more or less than the spacing between the first and second substrates 110 and 111. In the present disclosure, the bending region 50 includes all of the spacing between the first and second substrates 110 and 111 in a flat state before bending. However, the organic light emitting display device of the present disclosure is not limited thereto.

In an embodiment of the present disclosure, the bending region 50 can include the buffer layer 113 serving as an etching prevention layer, the gate insulating film 117, the interlayer insulating film 121, the connection wires 126, and the planarization layer 129. The bending region 50 can include the first bending region 50a where the connection wires 126 are located, and the second bending regions 50b where the reinforcement patterns 127 are located. The second bending regions 50b can be located on both sides of the first bending region 50a.

A plurality of reinforcement patterns 127 can be disposed spaced apart from each other at edge portions of the bending region 50, for example, in the second bending regions 50b provided on both sides of the first bending region 50a.

In this way, by disposing the plurality of reinforcement patterns 127 on the buffer layer 113 portion, which is an etching prevention layer located in the second bending regions 50b located at edge portions of the bending region 50, not only can the rigidity of the bending region 50 be increased, but also the bending orbit can be improved.

In addition, by disposing the plurality of reinforcement patterns 127 in the second bending regions 50b, damage can be prevented during handling such as transportation after manufacturing the display device and detachment after DB (debonding), and the application and curing process of the lower coating layer (micro coating layer) can be omitted, thereby simplifying the process.

In an embodiment of the present disclosure, the pad region 60 of the non-display region 20 outside of the bending region 50, for example, adjacent to the bending region 50, can include the buffer layer 113, the gate insulating film 117, the pad electrodes 119, and the interlayer insulating film 121 on the second substrate 111. However, the organic light emitting display device of the present disclosure is not limited thereto.

The pad electrodes 119 can be electrically connected through the connection wires 126. Accordingly, the connection wires 126 can transmit signals or voltages from external modules bonded to the pad electrodes 119 to the display region 30 or circuit parts such as the gate driver. However, the organic light emitting display device 100 of the present disclosure is not limited to the form and arrangement of the pad electrodes 119 as shown. The pad electrodes 119 can be metal patterns to which external modules, for example, flexible printed circuit board (FPCB) and chip on film (COF), are bonded.

In this way, by disposing the plurality of reinforcement patterns 127 in the second bending regions 50b, the micro coating layer (MCL) that was conventionally disposed to prevent cracks and disconnection of various wires located in the bending region 50 can be eliminated. For example, the micro coating layer can also have physical and chemical protective functions that can protect various wires disposed on the substrate 110 from external impact, moisture, or dust during the manufacturing process. However, in the present disclosure, since the plurality of reinforcement patterns 127 are provided in the second bending regions 50b to replace the role of the conventional micro coating layer, it may not be necessary to separately form a micro coating layer.

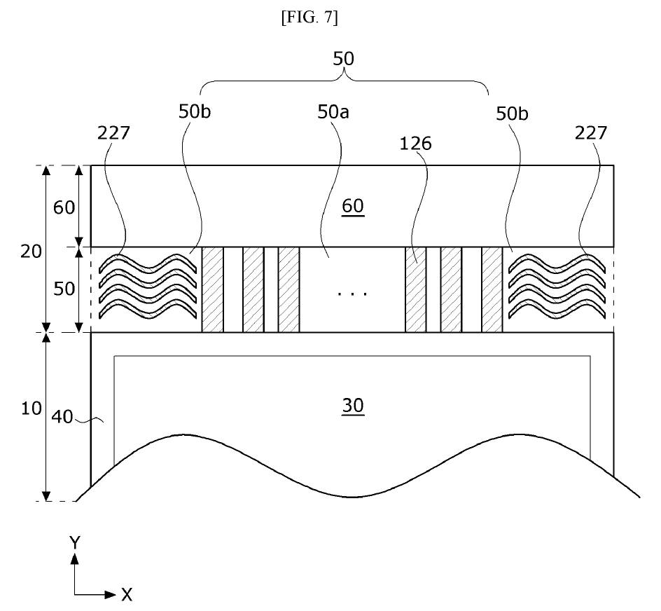

FIG. 7 is a plan view showing an organic light emitting display device according to a second embodiment of the present disclosure.

Referring to FIG. 7, the organic light emitting display device according to the second embodiment of the present disclosure is the same as the components of the first embodiment of the present disclosure in FIG. 4, except for the configuration of the reinforcement patterns 227 disposed in the second bending regions 50b of the bending region 50.

Here, the description will focus on the reinforcement patterns 227 disposed in the second bending regions 50b of the bending region 50.

In the second embodiment of the present disclosure, the organic light emitting display device can include the display region 10 and the non-display region 20. The display region 10 can include the pixel region 30 and the peripheral region 40 surrounding the pixel region 30.

The non-display region 20 can include the bending region 50 and the pad region 60. The bending region 50 can include the first bending region 50a and the second bending regions 50b located on both sides of the first bending region 50a.

A plurality of connection wires 126 can be disposed spaced apart within the first bending region 50a. A plurality of reinforcement patterns 227 can be disposed spaced apart from each other within the second bending regions 50b and can be disposed perpendicular to the plurality of connection wires 126. The plurality of reinforcement patterns 227 can be configured in a curved shape rather than a straight-line shape as in the case of the first embodiment of FIG. 3.

Therefore, since the length of the curved plurality of reinforcement patterns 227 is formed longer than the length of the reinforcement patterns (127 in FIG. 3) of the first embodiment, they can reinforce the rigidity of the bending region when bending the organic light emitting display device. This is because the curved reinforcement patterns 227 have a larger surface area contacting the second bending area 50b, for example, a surface area contacting the interlayer insulating film 121 on which they are disposed, so that the rigidity supporting the bending pressure can be improved accordingly.

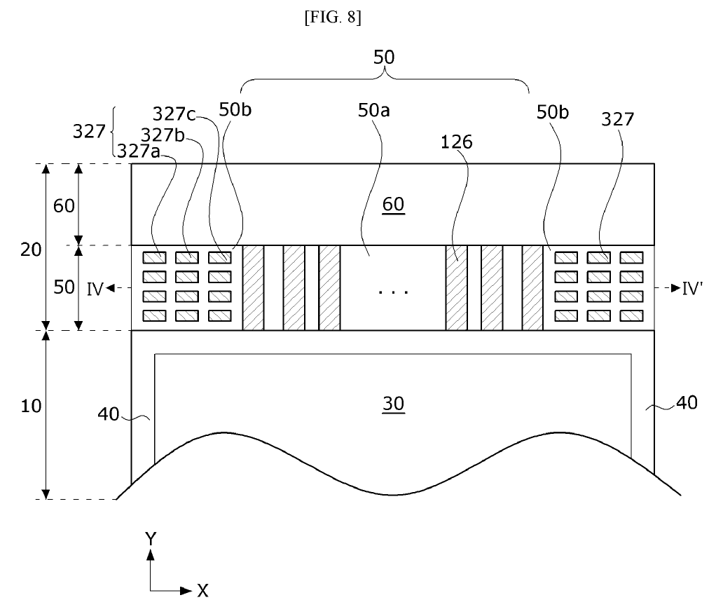

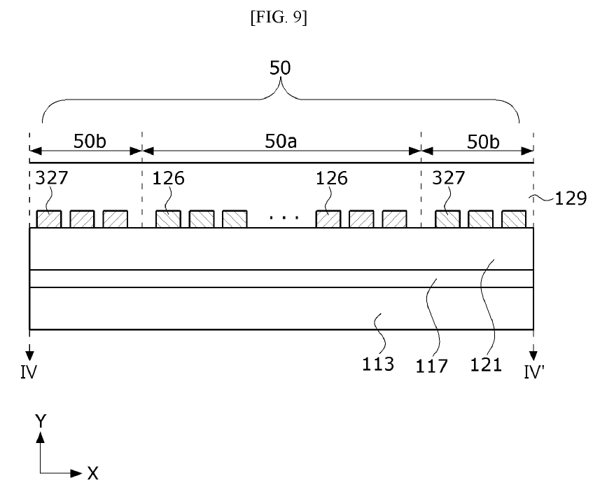

FIG. 8 is a plan view showing an organic light emitting display device according to a third embodiment of the present disclosure. FIG. 9 is a cross-sectional view taken along line IV-IV' of FIG. 8.

Referring to FIGS. 8 and 9, in the third embodiment of the present disclosure, the organic light emitting display device can include the display region 10 and the non-display region 20. The display region 10 can include the pixel region 30 and the peripheral region 40 surrounding the pixel region 30.

The non-display region 20 can include the bending region 50 and the pad region 60. The bending region 50 can include the first bending region 50a and the second bending regions 50b located on both sides of the first bending region 50a.

A plurality of connection wires 126 can be disposed spaced apart in the second direction Y within the first bending region 50a. A plurality of reinforcement patterns 327 can be disposed spaced apart from each other within the second bending regions 50b and can be disposed perpendicular to the plurality of connection wires 126. The plurality of reinforcement patterns 327 can be configured as a plurality of patterns at regular intervals rather than a straight-line shape as in the case of the first embodiment of FIG. 3. For example, each of the reinforcement patterns 327 can be composed of a first bar pattern 327a, a second bar pattern 327b, and a third bar pattern 327c spaced apart from each other in the first direction X.

Therefore, since each of the curved plurality of reinforcement patterns 327 is composed of a plurality of first to third bar patterns 327a, 327b, and 327c spaced apart from each other, they can reinforce the rigidity of the bending region when bending the organic light emitting display device.

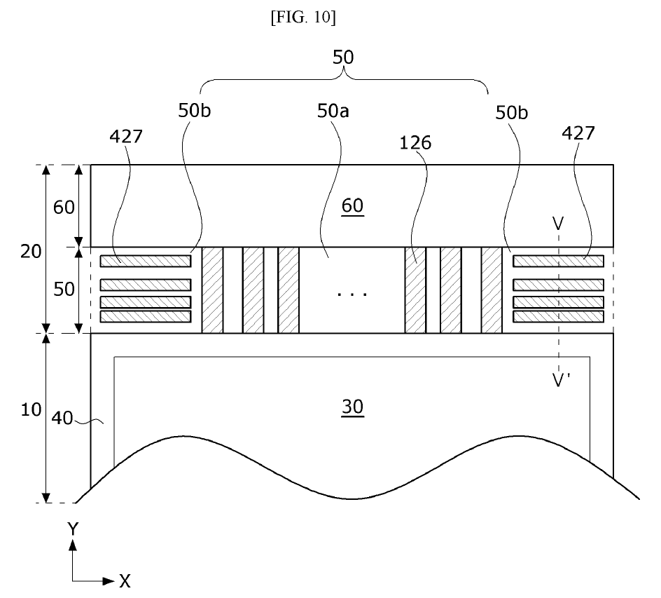

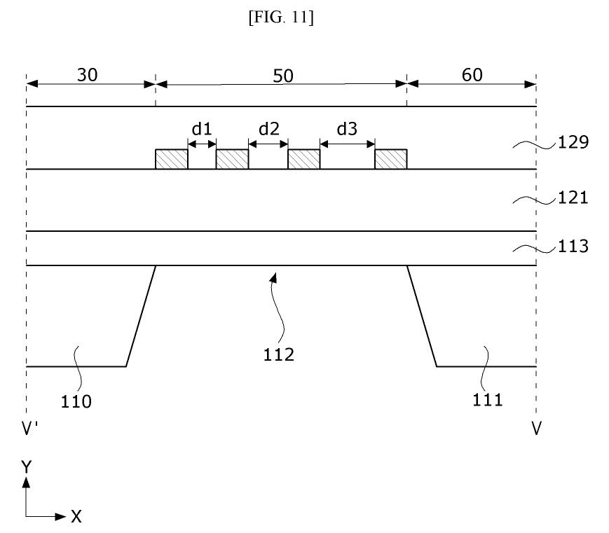

FIG. 10 is a plan view showing an organic light emitting display device according to a fourth embodiment of the present disclosure. FIG. 11 is a cross-sectional view taken along line V’-V of FIG. 10.

Referring to FIGS. 10 and 11, in the fourth embodiment of the present disclosure, the organic light emitting display device can include the display region 10 and the non-display region 20. The display region 10 can include the pixel region 30 and the peripheral region 40 surrounding the pixel region 30.

The non-display region 20 can include the bending region 50 and the pad region 60. The bending region 50 can include the first bending region 50a and the second bending regions 50b located on both sides of the first bending region 50a.

A plurality of connection wires 126 can be disposed spaced apart within the first bending region 50a. A plurality of reinforcement patterns 427 can be disposed spaced apart from each other within the second bending regions 50b and can be disposed perpendicular to the plurality of connection wires 126. The plurality of reinforcement patterns 427 may not linear reinforcement patterns as in the case of the first embodiment of FIG. 3, but rather can be arranged to become narrower toward the display area 10 from the pad area 60.

For example, referring to FIG. 11, the reinforcement patterns 427 can include a first reinforcement pattern, a second reinforcement pattern, a third reinforcement pattern, and a fourth reinforcement pattern, which are sequentially arranged from the display area 10 toward the pad area 60, however, the number of the reinforcement patterns 427 is not limited thereto. In this case, a first distance d1 can be a distance between the first and second reinforcement patterns, a second distance d2 can be a distance between the second and third reinforcement patterns, and a third distance d3 can be a distance between the third and fourth reinforcement patterns. For example, the first distance d1 can be narrower than the second distance d2, and the second distance d2 can be narrower than the third distance d3.

Therefore, in the fourth embodiment of the present disclosure, among the reinforcement patterns 427 disposed in the second bending regions 50b, by forming the distance between the reinforcement patterns 427 narrower toward the display region 10 from the pad region 60, the rigidity of the bending region can be reinforced accordingly during bending of the organic light emitting display device. This is because the second bending regions 50b close to the display region 10 side can receive more stress during bending, so by forming the distance between the reinforcement patterns 227 narrower in the second bending regions 50b close to the display region 10 side, the stress applied to the second bending regions 50b can be reduced and rigidity can be improved.

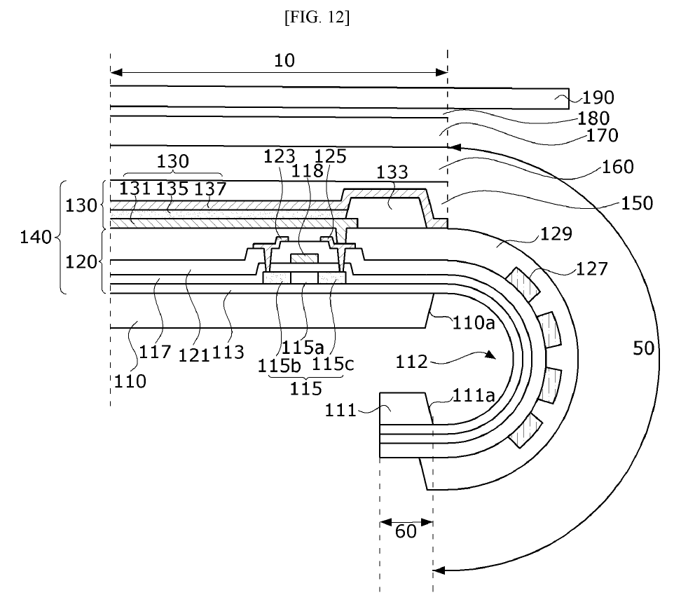

FIG. 12 is a schematic side cross-sectional view showing a bending state of the organic light emitting display device according to the first embodiment of the present disclosure.

Referring to FIG. 12, first substrate 110 and second substrate 111 can be disposed facing each other with the bending region 50 interposed therebetween. The first substrate 110 can include a front part, and second substrate 111 can include a rear part.

The first substrate 110 can include a pixel array 140 in the display region 10 and an encapsulation array 150 covering the pixel array 140, and can include a touch sensor array 160, a color filter array 170, and an adhesive layer 180 sequentially on encapsulation array 150.

The pixel array 140 can include a circuit layer 120 disposed on the first substrate 110 and the light emitting element 130 disposed on the circuit layer 120.

The encapsulation array 150 can cover the light emitting element 130 to seal the light emitting element 130. Here, the encapsulation array 150 can have a multi-insulating film structure in which organic films and inorganic films are alternately stacked. In this case, the inorganic film can block the penetration of moisture or oxygen. The organic film can planarize the surface of the inorganic film. When organic films and inorganic films are stacked in multiple layers, the movement path of moisture or oxygen becomes longer compared to a single layer, effectively preventing the penetration of moisture/oxygen that could affect the light-emitting device layer DL.

The touch sensor array 160 can include capacitive touch sensors that sense touch input based on changes in capacitance before and after touch input. The touch sensor array 160 can include metal wire patterns and insulating films that form the capacitance of touch sensors. The insulating films can insulate the intersecting portions of the metal wire patterns and planarize the surface of the touch sensor layer.

A polarizing plate omitted from the drawing can be attached on the touch sensor array 160. The polarizing plate can improve visibility and contrast ratio by converting the polarization of external light reflected by the metal patterns of the circuit layer 120. Here, the polarizing plate can be implemented as a polarizing plate in which a linear polarizing plate and a phase retardation film are bonded, or as a circular polarizing plate.

The color filter array 170 can be formed on the touch sensor array 160. The color filter array 170 can include red, green, and blue color filters. Additionally, the color filter array 170 can further include a black matrix pattern BM. The color filter array 170 can replace the role of a polarizing plate and increase color purity by absorbing a portion of the wavelength of light reflected from the circuit layer 120.

The display panel with the color filter array 170 disposed can improve the light transmittance of the display panel and improve the thickness and flexibility of the display panel by applying the color filter array 170, which has higher light transmittance than a polarizing plate, to the display panel. The color filter array 170 can include an organic film covering the color filter and the black matrix pattern. The extended portion of the organic film can cover the inorganic film residue or the first substrate 110 in the bezel region, for example, the edge region of the display panel.

A cover glass 190 can be attached on the color filter array 170 using the adhesive layer 180.

In the bending region 50, the buffer layer 113 applied as an etching prevention layer, the gate insulating film 117, the interlayer insulating film 121, the reinforcement patterns 127, and the planarization layer 129 can be disposed sequentially in the thickness direction from the inside of the display device. The bending region 50 can refer to the region between the first substrate 110 and the second substrate 111.

A plurality of reinforcement patterns 127 are disposed in the second bending regions 50b located on both sides of the first bending region 50a, which can prevent distortion of the organic light emitting display device 100. Since the reinforcement patterns 127 are disposed in the second bending regions 50b, stress on the buffer layer 113, which is disposed below the reinforcement patterns 127 and serves as an etching prevention layer, can be reduced compared to the existing structure.

Therefore, according to the present disclosure, when bending the organic light emitting display device 100, the reinforcement patterns 127 absorb bending stress and increase repulsive force, enabling detachment without distortion of the display device.

In the present disclosure, since the plurality of reinforcement patterns 127 are provided in the second bending regions 50b, they can replace the role of the conventional micro coating layer, eliminating the need to separately form a micro coating layer, thereby simplifying the manufacturing process accordingly.

Furthermore, in the present disclosure, by disposing the reinforcement patterns at the edge portions on both sides of the bending region, stress on the connection wires at the edge region of the substrate can be reduced or minimized when bending the organic light emitting display device 100.

Moreover, in the present disclosure, by disposing the reinforcement patterns at the edge portions on both sides of the bending region, reliability can be improved by alleviating stress which can be caused by expansion/contraction occurring in high and low temperature environments at the edge regions of the substrate.

Although the embodiments of the present disclosure have been described in more detail with reference to the accompanying drawings, the present disclosure is not necessarily limited to such embodiments, and can be variously modified within the scope thereof without departing from the technical spirit of the present disclosure.

Accordingly, the embodiments disclosed herein are provided for illustrative purposes and are not intended to limit the technical concept of the present disclosure, and the scope of the technical concept of the present disclosure is not limited to these embodiments.

Therefore it should be understood that the embodiments described above are illustrative in all aspects and are not intended to be limiting.

The scope of protection of the present invention should be construed on the basis of the following claims, and all technical concepts within the equivalent scope thereof should be construed as falling within the scope of the present. invention.

What is claimed is:

1. An organic light emitting display device comprising:
a first substrate including a plurality of sub-pixels;
a second substrate disposed on one side of the first substrate and including a pad region;
a bending region connecting the first substrate and the second substrate;
an etching prevention layer disposed in the bending region;
a circuit layer disposed on the first substrate; and
a light emitting element connected to the circuit layer,
wherein the bending region includes:
a first bending region where a plurality of connection wires are located; and
second bending regions provided on sides in a first direction of the first bending region, and
wherein a plurality of reinforcement patterns are provided in the second bending regions.

2. The organic light emitting display device of claim 1, wherein the plurality of reinforcement patterns are arranged perpendicular to the plurality of connection wires.

3. The organic light emitting display device of claim 2, wherein the plurality of reinforcement patterns are spaced apart from each other.

4. The organic light emitting display device of claim 3, wherein the plurality of reinforcement patterns are configured in a curved shape.

5. The organic light emitting display device of claim 3, wherein each of the plurality of reinforcement patterns includes a plurality of bar patterns that are spaced apart from each other.

6. The organic light emitting display device of claim 3, wherein intervals between the plurality of reinforcement patterns are formed to be narrower toward a display region from the pad region on the second bending regions.

7. The organic light emitting display device of claim 1, wherein the plurality of reinforcement patterns are disposed to overlap the etching prevention layer.

8. The organic light emitting display device of claim 1, wherein the plurality of reinforcement patterns are disposed on the etching prevention layer.

9. The organic light emitting display device of claim 1, wherein the light emitting element includes:
a first electrode electrically connected to a thin film transistor constituting the circuit layer,
an intermediate layer disposed on the first electrode, and
a second electrode disposed on the intermediate layer.

10. The organic light emitting display device of claim 1, wherein the first substrate and the second substrate are disposed below sides in a second direction of the bending region,
wherein the first substrate has a first inclined surface, and the second substrate has a second inclined surface different from the first inclined surface.

11. The organic light emitting display device of claim 10, wherein the first and second inclined surfaces face each other with a gap therebetween, and the plurality of reinforcement patterns are disposed above the gap.

12. An organic light emitting display device comprising:
a first substrate including a plurality of sub-pixels;
a second substrate disposed on one side of the first substrate and including a pad region; and
a bending region connecting the first substrate and the second substrate,
wherein the bending region includes a first bending region where a plurality of connection wires are located, and second bending regions provided on sides in a first direction of the first bending region, and
wherein a plurality of reinforcement patterns are provided in the second bending regions.

13. The organic light emitting display device of claim 12, wherein the plurality of reinforcement patterns are arranged perpendicular to the plurality of connection wires and are spaced apart from each other.

14. The organic light emitting display device of claim 13, wherein the plurality of reinforcement patterns do not cross the plurality of connection wires.

15. The organic light emitting display device of claim 12, wherein the plurality of reinforcement patterns are configured in a curved shape.

16. The organic light emitting display device of claim 12, wherein each of the plurality of reinforcement patterns includes a plurality of bar patterns that are spaced apart from each other.

17. The organic light emitting display device of claim 12, wherein intervals between the plurality of reinforcement patterns are formed to be narrower toward a display region from the pad region on the second bending regions.

18. The organic light emitting display device of claim 12, further comprising:
an etching prevention layer disposed in the bending region,
wherein the plurality of reinforcement patterns are disposed to overlap the etching prevention layer.

19. The organic light emitting display device of claim 12, further comprising:
an etching prevention layer disposed in the bending region;
a circuit layer disposed on the first substrate; and
a light emitting element connected to the circuit layer.

20. The organic light emitting display device of claim 12, wherein in the bending region, the first and second substrates having inclined end surfaces form a gap, and the plurality of reinforcement patterns are disposed above the gap.
